(19) United States
(12) Patent Application Publication
(10) Pub. No.: US 2024/0006373 A1
(43) Pub. Date: Jan. 4, 2024

(54) PACKAGE SUBSTRATE AND METHOD FOR FABRICATING CHIP ASSEMBLY

(71) Applicant: TONG HSING ELECTRONIC INDUSTRIES, LTD., Taipei City (TW)

(72) Inventors: YOU-WEI CHANG, Hsin-Chu County (TW); CHIEN-CHEN LEE, Hsin-Chu County (TW); LI-CHUN HUNG, Hsin-Chu County (TW)

(21) Appl. No.: 17/939,981

(22) Filed: Sep. 8, 2022

(30) Foreign Application Priority Data
Jun. 29, 2022 (TW) 111124166

(51) Int. Cl. H01L 23/00; H01L 23/544; H01L 23/498

(52) U.S. Cl. CPC H01L 24/97; H01L 23/544; H01L 23/49827; H01L 2223/54486; H01L 2224/95148; H01L 2223/54426; H01L 2224/97

(57) ABSTRACT

A package substrate and a method for fabricating a chip assembly are provided. The method includes: providing a substrate, which has an upper substrate surface and a lower substrate surface, the upper substrate surface is divided into a plurality of scribe line regions that define a plurality of die-bonding regions, and any adjacent two of the die-bonding regions are separated by the scribe line regions. The die-bonding region is provided with a substrate conductor and a core material body, the substrate conductor penetrates the substrate and has upper and lower conductive ends exposed on the upper and lower substrate surfaces, respectively, and the core material body is disposed adjacent to the substrate conductor in the substrate. The method further includes: fixing chips in the die-bonding regions, respectively; and performing a dicing process along a plurality of scribe lines defined by the scribe line regions to form chip assemblies.

### CROSS-REFERENCE TO RELATED PATENT APPLICATION

This application claims the benefit of priority to Taiwan Patent Application No. 111124166, filed on Jun. 29, 2022. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a substrate and a manufacturing method, and more particularly to a package substrate and a method for fabricating a chip assembly capable of reducing metal wastes.

### BACKGROUND OF THE DISCLOSURE

In the integrated circuit (IC) packaging industry, a large amount of waste is generated during an IC packaging process. With the rise of environmental awareness, regulatory controls on waste produced from the IC packaging industry have become increasingly strict. Especially, copper waste can cause extremely serious heavy metal pollution. Therefore, reduction of copper waste water generated during the packaging process of integrated circuits has become one of important issues to be addressed in the art.

### SUMMARY OF THE DISCLOSURE

In response to the above-referenced technical inadequacies, the present disclosure provides a package substrate and a method for fabricating a chip assembly capable of reducing metal wastes.

In one aspect, the present disclosure provides a method for fabricating a chip assembly, and the method includes: providing a substrate having an upper board surface and a lower board surface, in which a plurality of scribe line regions are arranged on the upper board surface to define a plurality of die-bonding regions and to separate any adjacent two of the plurality of die-bonding regions, and each of the plurality of die-bonding regions includes: a substrate conductor disposed to penetrate through the substrate, in which the substrate conductor has an upper conductive end and a lower conductive end that are exposed at the upper board surface and the lower board surface of the substrate, respectively; and a core material body disposed in the substrate and adjacent to the substrate conductor; performing a die bonding process to fix a plurality of chips in the plurality die-bonding regions, respectively, in which each of the plurality of chips is electrically connected to the corresponding substrate conductor through the upper conductive terminal thereof; and performing a dicing process along a plurality of scribe lines defined by the plurality of scribe line regions to form a plurality of chip assemblies.

In another aspect, the present disclosure provides a packaging substrate, which includes a substrate and a plurality of chips. The substrate has an upper board surface and a lower board surface, a plurality of scribe line regions are arranged on the upper board surface to define a plurality of die-bonding regions and to separate any adjacent two of the plurality of die-bonding regions from each other, and each of the plurality of die-bonding regions includes a substrate conductor and a core material body. The substrate conductor is disposed to penetrate through the substrate, and the substrate conductor has an upper conductive end and a lower conductive end that are exposed at the upper board surface and the lower board surface of the substrate, respectively. The core material body is disposed in the substrate and adjacent to the substrate conductor. The plurality of chips are fixedly disposed in the plurality of die-bonding regions, respectively, and each of the plurality of chips is electrically connected to the corresponding substrate conductor through the upper conductive terminal thereof.

Therefore, in the package substrate and the method for fabricating the chip assembly provided by the present disclosure, the substrate conductors can be arranged in regions other than the scribe lines, and the alignment marks that do not overlap with the scribe lines can be provided on paths that the scribe lines pass through, such that precise alignment can be achieved during the die bonding process and a singulation process, while avoiding generation of metal waste in the singulation process, so as to greatly reduce the release of metal waste.

In addition, in the package substrate and the method for fabricating the chip assembly provided by the present disclosure, a resin dicing blade can be further utilized, and redundant conductors can be arranged in a redundant region other than the scribe lines, the die-bonding regions and the marking regions. Therefore, in addition to maintaining accurate alignment and low risk of metal release, the substrate and method of the present disclosure can also ensure that a good copper plating rate of the substrate is achieved for the purpose of warpage control.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a method for fabricating a chip assembly according to one embodiment of the present disclosure;

FIG. 2 is a top view of a substrate according to one embodiment of the present disclosure;

FIG. 3 is a cross-sectional view of the substrate taken along line I-I of FIG. 2;

FIG. 4 is a top view of a substrate according to another embodiment of the present disclosure;

FIG. 5 is a cross-sectional view of the substrate taken along line II-II of FIG. 4;

FIG. 6 is a top view of a substrate according to another embodiment of the present disclosure;

FIG. 7 is a schematic diagram of a die bonding process and a dicing process according to one embodiment of the present disclosure; and

FIG. 8 is a schematic diagram of a chip assembly disposed on a carrier substrate according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

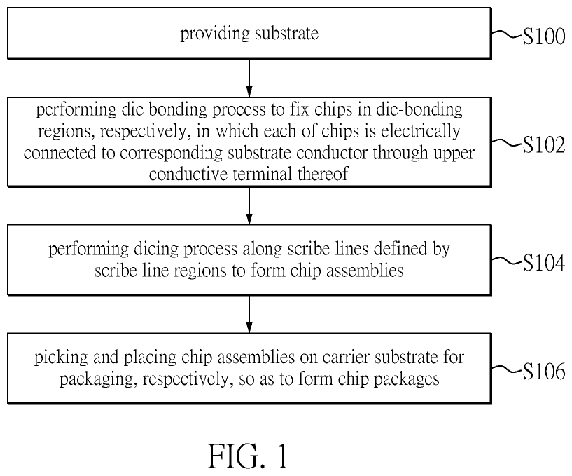

FIG. 1 is a flowchart of a method for fabricating a chip assembly according to one embodiment of the present disclosure. Referring to FIG. 1, a first embodiment of the present disclosure provides a method for fabricating a chip assembly, which includes the following steps:

Step S100: providing a substrate.

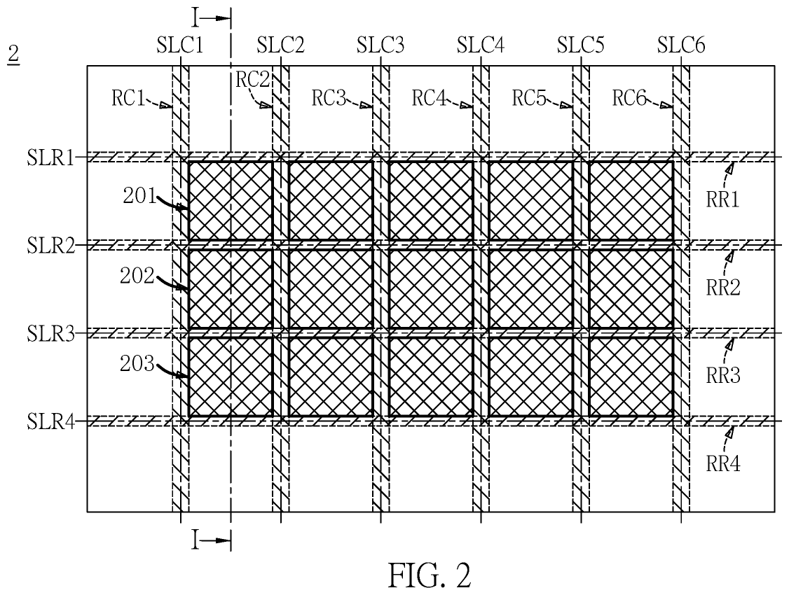

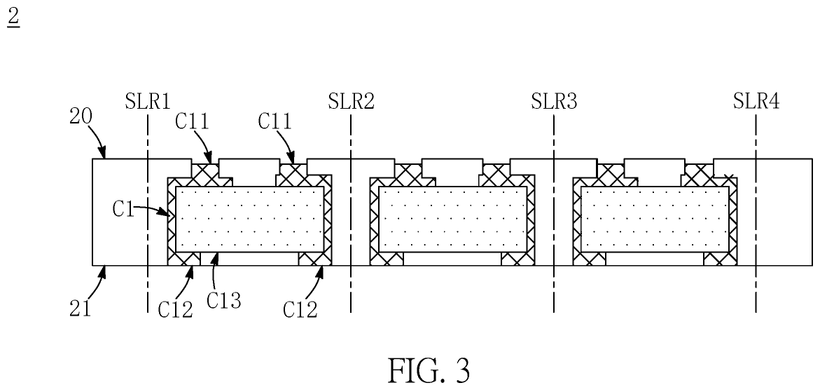

FIG. 2 is a top view of a substrate according to one embodiment of the present disclosure, and FIG. 3 is a cross-sectional view of the substrate taken along line I-I of FIG. 2.

Referring to FIGS. 2 and 3, the substrate 2 is rectangular in this embodiment, but the present disclosure is not limited thereto. The substrate 2 has an upper board surface 20 and a lower board surface 21 that are opposite to each other, and a plurality of scribe line regions RC1, RC2, . . . , RC6, RR1, RR2, RR3 and RR4 are arranged on the upper board surface 20. The scribe line regions RC1 to RC6 correspond to vertical scribe lines SLC1, SLC2, . . . , SLC6, respectively, and the scribe line regions RR1 to RR4 correspond to horizontal scribe lines SLR1, SLR2, SLR3, and SLC4, respectively. In other words, the scribe line regions RC1 to RC6 and the scribe lines SLC1 to SLC6 extend in a vertical direction, while the scribe line regions RR1 to RR4 and the scribe lines SLR1 to SLR4 extend in a horizontal direction. In addition, the dicing lines SLC1 to SLC6 respectively partially overlap with the scribe line regions RC1 to RC6 and are respectively parallel to extending directions of the scribe line regions RC1 to RC6. Similarly, the scribe lines SLR1 to SLR4 respectively partially overlap with the scribe line regions RR1 to RR4, and are respectively parallel to extending directions of the scribe line regions RR1 to RR4.

In addition, the scribe line regions RC1 to RC6 and RR1 to RR4 define a plurality of die-bonding regions (e.g., die-bonding regions 201, 202 and 203). For example, the die-bonding region 201 is defined by the scribe line regions RC1, RC2, RR1 and RR2, the die-bonding region 201 is defined by the scribe line regions RC1, RC2, RR1 and RR2, and the die-bonding region 201 is defined by the scribe line region RC1, RC2, RR1 and RR2. In addition, each of the die-bonding regions is used to set a chip in the subsequent processes, and conductive contacts exposed on the upper board surface 20 can be electrically connected to the set chip, but the embodiment of the present disclosure does not limit implementations of the conductive contacts.

In addition, the scribe line regions can separate any adjacent two of the die-bonding regions from each other. For example, the scribe line region RR2 can separate the adjacent die-bonding regions 201 and 202, and the scribe line region RR3 can separate the adjacent die-bonding regions 202 and 203.

In the step of providing the substrate in this embodiment, the substrate 2 can be fully cleaned, and can be a printed circuit board that is pre-planned for the above-mentioned dicing lines, scribe line regions, die-bonding regions and other regions, and a substrate conductor and a core material body are disposed in each of the die-bonding regions.

As shown in FIG. 3, a substrate conductor C1 is disposed in the die-bonding region 201 and penetrates through the substrate 2. The substrate conductor C1 has an upper conductive end C11 and a lower conductive end C12 exposed on the upper board surface 20 and the lower board surface 21 of the substrate 2, respectively. In addition, a core material body C13 is also disposed in the die-bonding region 201 and in the substrate 2, and is adjacent to the substrate conductor C1. It should be noted that the upper board surface 20 and the lower board surface 21 of the substrate 2 have protective layers for covering the substrate conductor C1 and the core material body C13 therein. For example, the substrate conductor C1 can be copper foil, and can be in a form of grids, so as to provide electrical paths required by the chip. Furthermore, the core material body C13 can be, for example, glass fiber, and the protective layer can be, for example, a solder mask, which is used to protect the conductor C1 (e.g., copper foil) of the substrate 2 from being directly exposed to atmosphere and being oxidized and accidentally contacted with solder to affect a functionality of the printed circuit board. The substrate conductor C1 can be made of conductive metals such as copper, aluminum, copper-aluminum alloy, silver, and the like.

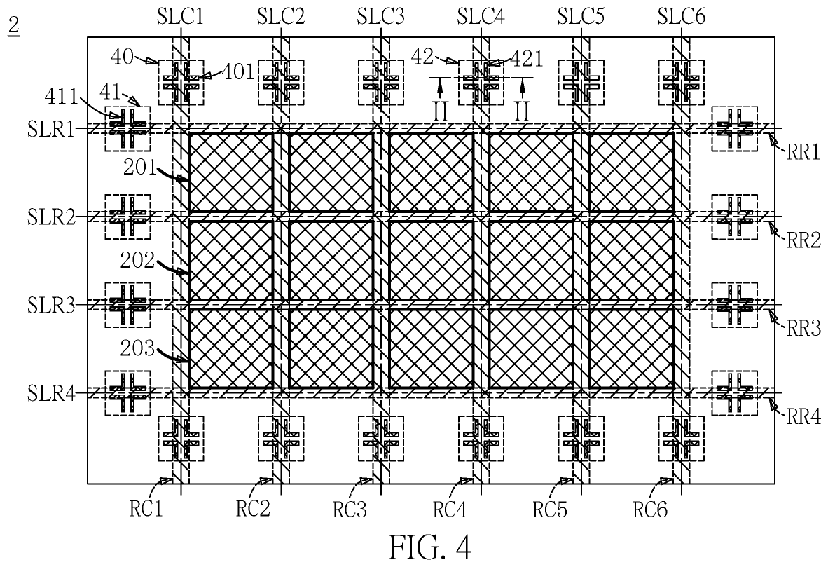

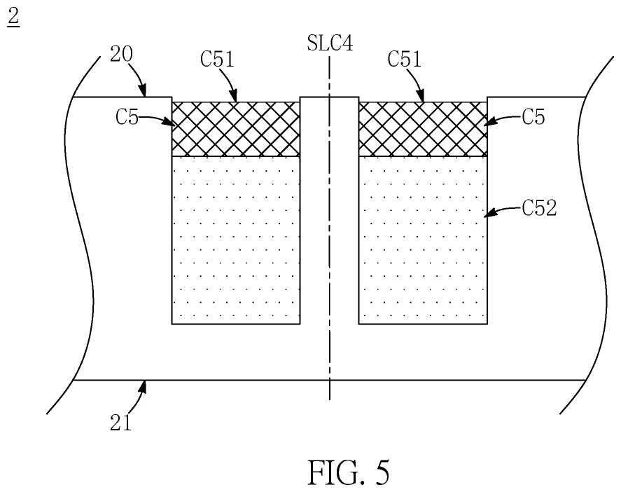

However, the substrate provided in step S100 is not limited to the substrate shown in FIGS. 2 and 3. For example, reference can be further made to FIGS. 4 and 5, FIG. 4 is a top view of a substrate according to another embodiment of the present disclosure, and FIG. 5 is a cross-sectional view of the substrate taken along line II-II of FIG. 4.

As shown in FIG. 4, a plurality of marking regions (e.g., marking regions 40, 41, 42) surrounding the die-bonding regions are further arranged on the upper board surface 20 of the substrate 2 for forming a plurality of alignment marks on the substrate 2 (e.g., alignment marks 401, 411, 421). In detail, the alignment marks can be used to locate the chip regions during a die bonding process for setting chips, thereby disposing the chips in the die-bonding regions, respectively. In addition, the alignment marks can also be used to locate the aforementioned scribe lines (i.e., the scribe lines SLC1 to SLC6 and SLR1 to SLR4) in the subsequent dicing process to divide the package substrate into individual chip components.

In more detail, as shown in FIG. 5, each of the marking regions (e.g., marking region 42) in step S100 is provided with a marking conductor, which has an upper marking end C51 exposed at the upper board surface 20 of the substrate 2 to serve as one of the plurality of alignment marks (e.g., alignment mark 421). Moreover, the plurality of dicing lines partially overlap with the plurality of marking regions, and the marking conductor in each of the plurality of marking regions is not disposed in an overlapping portion that the plurality of scribe lines overlap with the plurality of marking regions. For example, the scribe line SLC4 can partially overlap the marking region 42, and the marking conductor C5 of the marking region 42 is not disposed in an overlapping portion that the marking region 42 overlaps with the scribe line SLC4. Similarly, the marker conductor C5 can be made of conductive metal such as copper, aluminum, copper-aluminum alloy, silver, and the like.

Furthermore, as shown in FIG. 5, the marking conductor C5 in the marking region 42 can be further disposed on the core material body C52, but the above is only an example, and the present disclosure is not limited thereto. That is, in some embodiments, the substrate 2 in the marking region 42 can only include the marking conductor C5 and the protective layer, but not the core material body C52.

In addition, from the top view of FIG. 4, the alignment marks 401, 411 and 421 can be respectively formed of four L-shaped marks placed symmetrically to form a symmetrical pattern, and center points of the marking regions 40, 41 and 42 are respectively used as geometric center points of the symmetrical patterns. Furthermore, since the center points of the marking regions 40, 41, and 42 are respectively set on the scribe lines SLC1 and SLR1, the symmetrical pattern formed by the alignment marks can accurately define locations of the cutting lines, so as to achieve precise alignment and dicing in the subsequent dicing process. It should be noted that the present disclosure is not limited to the L-shaped marks, and any geometric figures can be used to form the above-mentioned symmetrical pattern, and the center point of the marking region is taken as the symmetrical geometric center point.

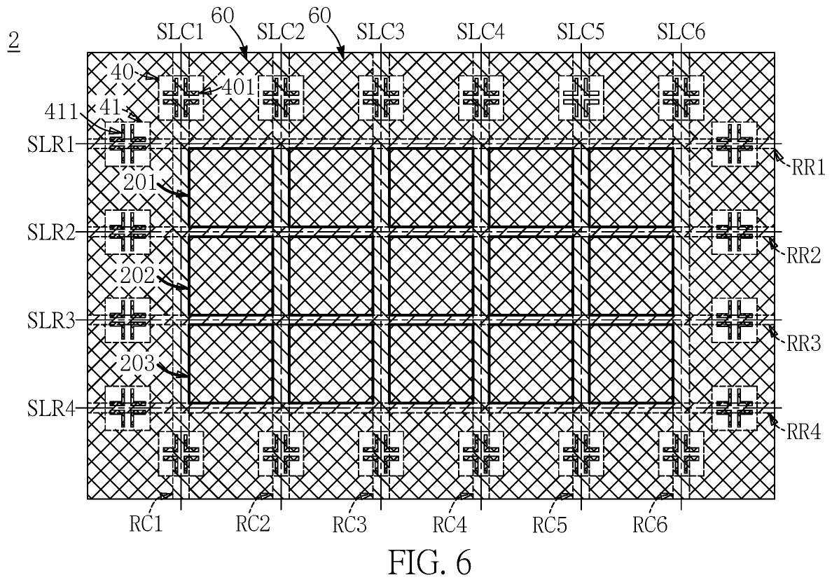

However, the substrate provided in step S100 is not limited to the substrate shown in FIGS. 2 to 5. For example, further reference can be made to FIG. 6, which is a top view of a substrate according to another embodiment of the present disclosure.

In yet another embodiment of the present disclosure, in step S100, a redundant region is further arranged on the upper board surface 20 of the substrate 2 to surround the die-bonding regions (e.g., die-bonding regions 201, 202 and 203) and the marking regions. (e.g., marking regions 40 and 41). To be more precise, on the upper board surface 20 of the substrate 2, regions other than all the aforementioned scribe line regions, die-bonding regions and marking regions can be regarded as the redundant region.

It should be noted that, in the embodiments shown in FIGS. 2 to 5, for the substrate 2 provided in step S100, no conductors are provided in the redundant region, and therefore, metal waste that may be generated in a packaging process can be greatly reduced.

However, under some process conditions, in order to more precisely control warpage of the conductors in the substrate 2 during the processes, coverage of the conductors in the substrate 2 (from top view) needs to be maintained above a certain degree. Therefore, in the step S100 of providing the substrate 2, redundant conductors 60 are disposed in the redundant region, and the redundant conductors 60 are not disposed in an overlapping portion where the scribe lines (that is, the scribe lines SLC1 to SLC6 and SLR1 to SLR4) overlap the redundant region. Similarly, redundant electrical conductors 60 can be made of conductive metals such as copper, aluminum, copper-aluminum alloys, silver, and the like.

In the embodiment of FIG. 6, although the scribe line regions do not overlap with the redundant region, the scribe line regions can partially overlap with the redundant region, and only regions required in the dicing process are reserved without needing to dispose the redundant conductors. That is, portions of the scribe line regions that do not overlap with the scribe lines can also be used as the redundant region for disposing the redundant conductors.

Step S102: performing a die bonding process to fix a plurality of chips in the plurality die-bonding regions, respectively, in which each of the plurality of chips is electrically connected to the corresponding substrate conductor through the upper conductive terminal thereof.

Step S104: performing a dicing process along the scribe lines defined by the scribe line regions to form a plurality of chip assemblies.

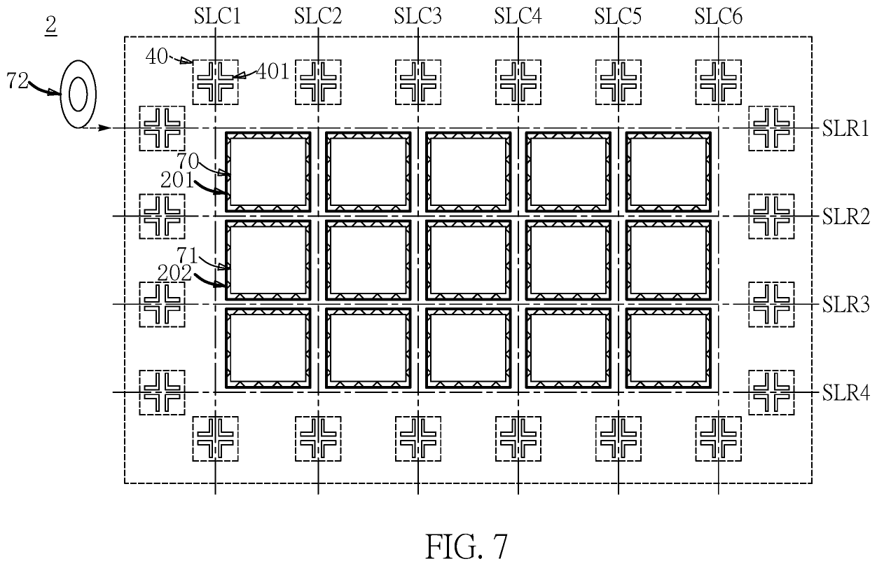

For example, reference can be made to FIG. 7, which is a schematic diagram of a die bonding process and a dicing process according to one embodiment of the present disclosure. As shown in FIG. 7, chips 70 and 71 can be disposed in die-bonding regions 201 and 202, respectively, and can be electrically connected to the upper conductive ends of the substrate conductors in the die-bonding regions 201 and 202 by soldering. Since the way that an electrical connection can be established between the chip and the conductor of the substrate is a technique familiar to those skilled in the art, descriptions with regard to the same are omitted hereinafter. It should be noted that, in the process of arranging the chips in the die-bonding regions, alignment marks (e.g., alignment marks 401) can be used for alignment, for example, an image capture device (such as a camera) can be used to photograph the substrate on a stage, locations of the die-bonding regions can be confirmed by analyzing positions of the alignment marks through an image processing equipment (such as a computer equipment including an graphic processor, a central processing unit and a memory), and then a robotic arm can be controlled to pick the chips and place the chips in the die-bonding regions. As the chips are completely set, the package substrate (including the substrate and a plurality of chips) provided by the embodiment of the present disclosure is also completed.

Next, the dicing process can be performed by analyzing the locations of the alignment marks in a similar manner to confirm locations of the scribe lines (e.g., scribe lines SLC1 to SLC6 and SLR1 to SLR4), and then a dicing tool 72 is used to cut along the scribe lines to form a plurality of chip assemblies. It should be noted that the dicing tool 72 made of resin can be utilized to reduce pollution of metal waste, and since the scribe lines do not overlap with any metal conductors (including the substrate conductors, the marking conductors and the redundant conductors) in the substrate provided by the present disclosure, no metal waste (for example, copper waste) is generated during the cutting process; and since the cutting tool 72 is not in direct contact with the metal conductors, a service life of the cutting tool 72 can be further improved, and manufacturing costs can be reduced.

Step S106: picking and placing the plurality of chip assemblies on a plurality of carrier substrate for packaging, respectively, so as to form a plurality of chip packages.

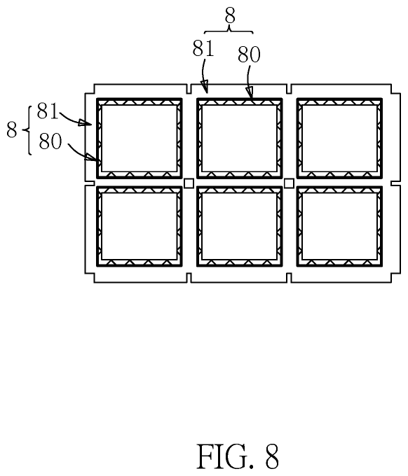

For example, reference can be made to FIG. 8, which is a schematic diagram of a chip assembly disposed on a carrier substrate according to one embodiment of the present disclosure. As shown in FIG. 8, the chip assembly 80 can be picked up and placed on a carrier board 81 (which can be integrally formed or divided into multiple individual carrier boards) by controlling a robot arm for packaging, so as to form the chip packages 8. Since the method of picking up and placing the chip components on the carrier board for packaging is a technique familiar to those skilled in the art, relevant descriptions are omitted herein.

### Beneficial Effects of the Embodiments

In conclusion, in the package substrate and the method for fabricating the chip assembly provided by the present disclosure, the substrate conductors can be arranged in regions other than the scribe lines, and the alignment marks that do not overlap with the scribe lines can be provided on paths that the scribe lines pass through, such that precise alignment can be achieved during the die bonding process and a singulation process, while avoiding generation of metal waste in the singulation process, so as to greatly reduce the release of metal waste.

In addition, in the package substrate and the method for fabricating the chip assembly provided by the present disclosure, a resin dicing blade can be further utilized, and redundant conductors can be arranged in a redundant region other than the scribe lines, the die-bonding regions and the marking regions. Therefore, in addition to maintaining accurate alignment function and low risk of metal release, the substrate and method of the present disclosure can also ensure that a good the copper plating rate of the substrate is achieved for the purpose of warpage control.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method for fabricating a chip assembly, the method comprising:
providing a substrate having an upper board surface and a lower board surface, wherein a plurality of scribe line regions are arranged on the upper board surface to define a plurality of die-bonding regions and to separate any adjacent two of the plurality of die-bonding regions from each other, and each of the plurality of die-bonding regions includes:
a substrate conductor disposed to penetrate through the substrate, wherein the substrate conductor has an upper conductive end and a lower conductive end that are exposed at the upper board surface and the lower board surface of the substrate, respectively; and
a core material body disposed in the substrate and adjacent to the substrate conductor;
performing a die bonding process to fix a plurality of chips in the plurality die-bonding regions, respectively, wherein each of the plurality of chips is electrically connected to the corresponding substrate conductor through the upper conductive terminal thereof; and
performing a dicing process along a plurality of scribe lines defined by the plurality of scribe line regions to form a plurality of chip assemblies.

2. The method according to claim 1, further comprising:
picking and placing the plurality of chip assemblies on a plurality of carrier substrate for packaging, respectively, so as to form a plurality of chip packages.

3. The method according to claim 1, wherein, in the step of providing the substrate, a plurality of marking regions that surrounds the plurality of die-bonding regions are further arranged on the upper board surface for disposing a plurality of alignment marks on the substrate, so as to locate the plurality of die-bonding regions during the die bonding process and allow the plurality of chips to be disposed in the die-bonding regions, respectively.

4. The method according to claim 3, wherein, in the step of providing the substrate, each of the marking regions is provided with a marking conductor, which has an upper marking end exposed at the upper board surface of the substrate to serve as one of the plurality of alignment marks.

5. The method according to claim 4, wherein, in the step of providing the substrate, the plurality of dicing lines partially overlap the plurality of marking regions, and the marking conductor in each of the plurality of marking regions is not disposed in an overlapping portion where the plurality of scribe lines overlap with the plurality of marking regions.

6. The method according to claim 4, wherein, in the step of providing the substrate, a redundant region is further arranged on the upper board surface of the substrate to surround the plurality of die-bonding regions and the plurality of marking regions.

7. The method according to claim 6, wherein in the step of providing the substrate, no electrical conductor is provided in the redundant region.

8. The method according to claim 6, wherein, in the step of providing the substrate, the redundant region is provided with a redundant electrical conductor, the plurality of scribe line regions are partially overlapped with the redundant region, and the redundant conductor is not disposed in an overlapping portion where the plurality of scribe lines overlap with the redundant region.

9. The method according to claim 1, wherein in the step of the dicing process, a resin dicing blade is utilized for dicing.

10. A package substrate, comprising:
a substrate having an upper board surface and a lower board surface, wherein a plurality of scribe line regions are arranged on the upper board surface to define a plurality of die-bonding regions and to separate any adjacent two of the plurality of die-bonding regions, and each of the plurality of die-bonding regions includes:
a substrate conductor disposed to penetrate through the substrate, wherein the substrate conductor has an upper conductive end and a lower conductive end that are exposed at the upper board surface and the lower board surface of the substrate, respectively; and
a core material body disposed in the substrate and adjacent to the substrate conductor; and
a plurality of chips fixedly disposed in the plurality die-bonding regions, respectively, wherein each of the plurality of chips is electrically connected to the corresponding substrate conductor through the upper conductive terminal thereof;
wherein the plurality of scribe line regions define a plurality of scribe lines, and a dicing process is performed by dicing along the plurality of scribe lines to form a plurality of chip assemblies.

11. The package substrate according to claim 10, wherein a plurality of marking regions that surrounds the plurality of die-bonding regions are further arranged on the upper board surface for disposing a plurality of alignment marks on the substrate, so as to locate the plurality of die-bonding regions during a die bonding process and allow the plurality of chips to be disposed in the die-bonding regions, respectively.

12. The package substrate according to claim 11, wherein each of the marking regions is provided with a marking conductor, which has an upper marking end exposed at the upper board surface of the substrate to serve as one of the plurality of alignment marks.

13. The package substrate according to claim 12, wherein the plurality of dicing lines partially overlap the plurality of marking regions, and the marking conductor in each of the plurality of marking regions is not disposed in an overlapping portion where the plurality of scribe lines overlap with the plurality of marking regions.

14. The package substrate according to claim 12, wherein a redundant region is further arranged on the upper board surface of the substrate to surround the plurality of die-bonding regions and the plurality of marking regions.

15. The package substrate according to claim 14, wherein no electrical conductor is provided in the redundant region.

16. The package substrate according to claim 14, wherein the redundant region is provided with a redundant electrical conductor, the plurality of scribe line regions are partially overlapped with the redundant region, and the redundant conductor is not disposed in an overlapping portion where the plurality of scribe lines overlap the redundant region.
